(19) United States
(12) Patent Application Publication
(10) Pub. No.: US 2025/0220924 A1
(43) Pub. Date: Jul. 3, 2025

(54) SEMICONDUCTOR DEVICE AND METHOD OF MANUFACTURING THE SEMICONDUCTOR DEVICE

(71) Applicant: SK hynix Inc., Icheon (KR)

(72) Inventors: Cheol Joon PARK, Icheon-si (KR); Yoon Mo KOO, Icheon-si (KR)

(21) Appl. No.: 18/618,951

(22) Filed: Mar. 27, 2024

(30) Foreign Application Priority Data
Dec. 27, 2023 (KR) 10-2023-0192618

(51) Int. Cl. H10B 63/00; H10B 61/00

(52) U.S. Cl. CPC H10B 63/845; H10B 61/00

(57) ABSTRACT

A semiconductor device may include a stack structure including first access lines and first insulating layers alternately stacked and extending in a first direction, first air gaps positioned to correspond to the first insulating layers and extending in the first direction along a sidewall of the stack structure, an electrode pillar extending through the stack structure, and second air gaps positioned to correspond to the first insulating layers and surrounding the electrode pillar.

### CROSS-REFERENCE TO RELATED APPLICATION

This application claims priority under 35 U.S.C. § 119 to Korean Patent Application No. 10-2023-0192618 filed on Dec. 27, 2023, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods thereof are being developed in order to improve operation reliability of the semiconductor device.

### SUMMARY

According to an embodiment of the present disclosure, a semiconductor device may include a stack structure including first access lines and first insulating layers that are alternately stacked, and the stack structure extending in a first direction, first air gaps positioned to correspond to the first insulating layers, and the first air gaps each extending in the first direction along a sidewall of the stack structure, an electrode pillar extending through the stack structure, and second air gaps positioned to correspond to the first insulating layers and surrounding the electrode pillar.

According to an embodiment of the present disclosure, a semiconductor device may include first access lines extending in a first direction, second access lines extending in a second direction that crosses the first direction, electrode pillars extending through the first access lines and connected to the second access lines, and insulating pillars extending through the first access lines and connected to the second access lines, at least one of the insulating pillars including an air gap therein.

According to an embodiment of the present disclosure, a method of manufacturing a semiconductor device may include forming a stack structure including first access lines and first insulating layers that are alternately stacked, and the stack structure extending in a first direction, forming first openings by selectively etching the first insulating layers exposed through a sidewall of the stack structure, forming first sealing layers defining first air gaps positioned in the first openings, and the first air gaps extending in the first direction, forming first holes extending through the stack structure, forming second openings by selectively etching the first insulating layers exposed through the first holes, forming second sealing layers defining second air gaps positioned in the second openings, and forming electrode pillars in the first holes.

According to an embodiment of the present disclosure, a method of manufacturing a semiconductor device may include forming stack structures, wherein each of the stack structures includes first access lines and first insulating layers that are alternately stacked, and extends in a first direction, forming insulating pillars extending through the stack structures, wherein at least one of the insulating pillars includes an air gap therein, forming electrode pillars extending through the stack structures, and forming second access lines connected to the insulating pillars and the electrode pillars and extending in a second direction that crosses the first direction.

### BRIEF DESCRIPTION OF THE DRAWINGS

FIGS. 1A to 1C are cross-sectional views illustrating a structure of a semiconductor device according to an embodiment of the present disclosure.

FIGS. 2A to 2C are diagrams illustrating a structure of a semiconductor device according to another embodiment of the present disclosure.

FIGS. 3, 4A, 4B, 5, 6A, 6B, 7A, 7B, 8, 9A, 9B, 10A, 10B, 11, 12A, and 12B illustrate a method of manufacturing a semiconductor device according to an embodiment of the present disclosure.

FIGS. 13A to 15A and 13B to 15B illustrate a method of manufacturing a semiconductor device according to an embodiment of the present disclosure.

FIGS. 16, 17A, 17B, 18, 19A, 19B, 20, 21A, and 21B illustrate a method of manufacturing a semiconductor device according to an embodiment of the present disclosure.

FIGS. 22, 23A, 23B, 24, 25A, 25B, 26A, and 26B illustrate a method of manufacturing a semiconductor device according to an embodiment of the present disclosure.

### DETAILED DESCRIPTION

Hereinafter, embodiments according to the technical spirit of the present disclosure are described with reference to the accompanying drawings.

The drawings may not necessarily be to scale and in some instances, proportions of at least some of structures in the drawings may have been exaggerated in order to clearly illustrate certain features of various embodiments. In presenting a specific example in a drawing or description having two or more layers in a multi-layer structure, the relative positioning relationship of such layers, or the sequence of arranging the layers, as shown, reflects a particular embodiment for the described or illustrated example, and a different relative positioning relationship or sequence of arranging the layers may be possible in accordance with other embodiments. In addition, a described or illustrated example of a multi-layer structure may not reflect all layers present in that particular multilayer structure (e.g., one or more additional layers may be present between two illustrated layers). For example, when a first layer in a described or illustrated multi-layer structure is referred to as being “on” or “over” a second layer or “on” or “over” a substrate, the first layer may be directly formed on the second layer or the substrate, but may also represent a structure where one or more other intermediate layers may exist between the first layer and the second layer or the substrate.

As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, or only C, or both A and B, or both A and C, or both B and C, or all of A and B and C,” and so on.

The present disclosure provides embodiments introducing a semiconductor device characterized by a stable three-dimensional structure and a method of manufacturing the semiconductor device.

Consequently, the integration degree of the semiconductor device may be improved, facilitated by a stable structure and enhanced reliability.

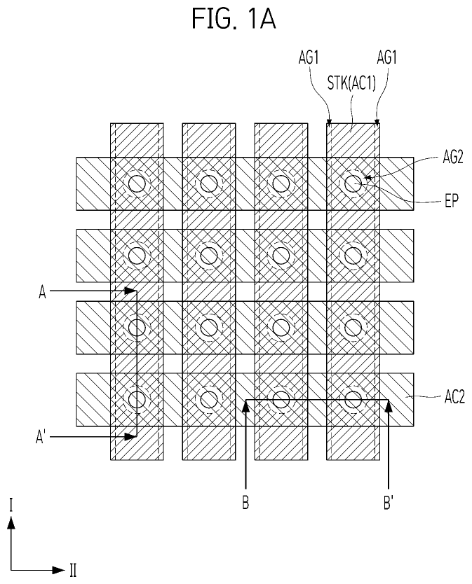

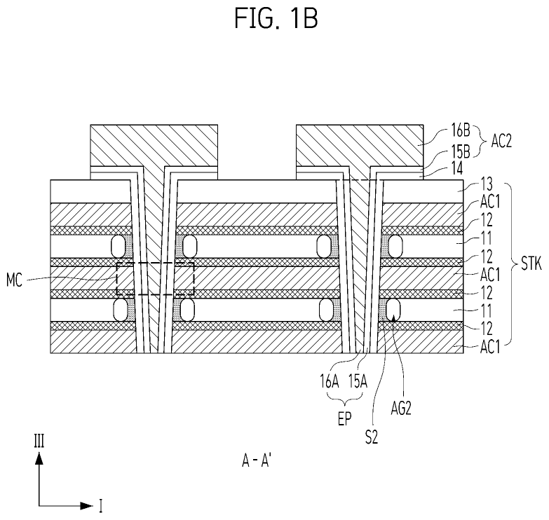

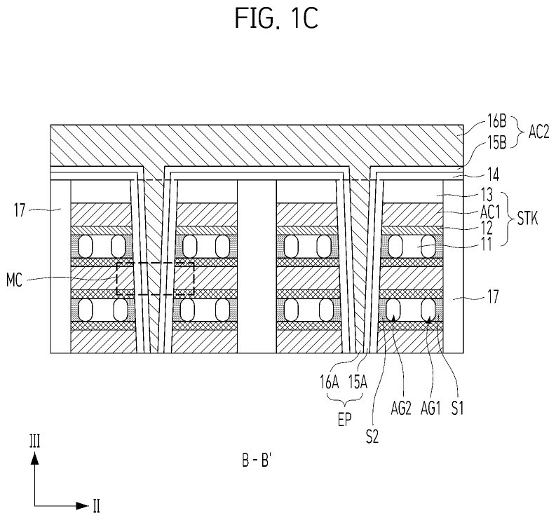

FIGS. 1A to 1C are cross-sectional views illustrating a structure of a semiconductor device according to an embodiment of the present disclosure. FIG. 1A is a plan view, FIG. 1B is a cross-sectional view taken along line A-A′ of FIG. 1A, and FIG. 1C is a cross-sectional view taken along line B-B′ of FIG. 1A.

For illustrative convenience, the embodiment will be described with a specific focus on one of stack structures STK included in the semiconductor device.

Referring to FIGS. 1A to 1C, the semiconductor device may include a stack structure STK, first air gaps AG1, electrode pillars EP, and second air gaps AG2. The semiconductor device may further include at least one of a second access line AC2, first sealing layers S1, second sealing layers S2, and a variable resistance layer 14.

The stack structure STK may include first access lines AC1 and first insulating layers 11 that are alternately stacked in a third direction (or vertical direction) III. In an embodiment, while the second access line AC2 may function as either a bit line or a word line, the first access lines AC1 may serve as word lines or bit lines. The first access lines AC1 may include a conductive material such as polysilicon, tungsten (W), or molybdenum (Mo).

The stack structure STK may further include second insulating layers 12, each of which is positioned between each of the first access lines AC1 and its corresponding one of the first insulating layers 11 in the third direction III. The first insulating layer 11 and the second insulating layer 12 may include materials having different dielectric constants. The first insulating layer 11 may include a material having a dielectric constant lower than that of the second insulating layer 12. The first insulating layer 11 may include a low dielectric constant material such as SiCOH. The second insulating layer 12 may include a material having a higher etch selectivity in comparison to the first insulating layer 11. In an embodiment, the first insulating layer 11 may include an oxide such as tetra ethyl ortho silicate (TEOS), and the second insulating layer 12 may include a nitride.

The stack structure STK may further include a hard mask 13. The hard mask 13 may be used as an etch barrier in a manufacturing process. The hard mask 13 may be disposed at the top of the stack structure STK.

The stack structure STK may extend in a first direction I. Insulating layers 17 may be positioned between stack structures STK arranged in parallel in a second direction II that crosses the first direction I. Therefore, the stack structures STK arranged in the second direction II and the insulating layers 17 may be alternately arranged along the second direction II. The insulating layers 17 may include an insulating material such as an oxide.

Electrode pillars EP may be arranged both in the first direction I and the second direction II, and may extend, in the third direction III, through the stack structures STK. Here, the third direction III may be a direction perpendicular to a plane defined by the first direction I and the second direction II. Each of the electrode pillars EP may include a first conductive layer 15A and a second conductive layer 16A. Here, the first conductive layer 15A and the second conductive layer 16A may include materials with different resistivities. In an embodiment, the first conductive layer 15A may include a carbon layer, and the second conductive layer 16A may include a metal such as tungsten.

The variable resistance layer 14 may surround a sidewall of the electrode pillar EP. The variable resistance layer 14 may be positioned between the electrode pillar EP and the stack structure STK including the first access lines AC1, the second insulating layers 12, and the first insulating layers 11 that are stacked in the third direction III.

The variable resistance layer 14 may include a resistive material. Data may be stored in the variable resistance layer 14 by generating or disappearing an electrical path in the variable resistance layer 14. In an embodiment, the variable resistance layer 14 may include a transition metal oxide or a metal oxide, such as a perovskite-based material.

In an embodiment, the variable resistance layer 14 may have an MTJ (Magnetic Tunnel Junction) structure including a magnetization pinned layer, a tunnel barrier layer, and a magnetization free layer. Data may be stored in the MTJ structure according to a change in a magnetization direction of the magnetization free layer with respect to a magnetization direction of the magnetization pinned layer. In an embodiment, the magnetization pinned layer and the magnetization free layer may include a magnetic material, and the tunnel barrier layer may include a metal oxide.

In another embodiment, the variable resistance layer 14 may include a phase change material or a chalcogenide-based material. The variable resistance layer 14 may change a phase according to a program operation. In an embodiment, the variable resistance layer 14 may have a low-resistance crystalline state by performing a set operation, and may have a high-resistance amorphous state by performing a reset operation. Therefore, data may be stored in a memory cell by using a resistance difference according to the phase of the variable resistance layer 14.

In still another embodiment, the variable resistance layer 14 may include a variable resistance material of which a resistance changes without a phase change, and may include a chalcogenide-based material. The variable resistance layer 14 may maintain the phase after the program operation. In an embodiment, the variable resistance layer 14 may have an amorphous state and maintain the amorphous state without changing to a crystalline state after the program operation. A threshold voltage of the memory cell may be changed according to a program voltage applied to the memory cell, and the memory cell may be programmed to at least two states. In an embodiment, the memory cell may be programmed to a set state or a reset state using a program voltage of different polarities. Therefore, data may be stored in the memory cell using a threshold voltage difference between memory cells.

The second access line AC2 may extend in the second direction II and be positioned on a plurality of stack structures STK arranged in parallel in the second direction II. A plurality of second access lines AC2 may be arranged in parallel along the first direction I. The second access line AC2 may be electrically connected to a plurality of electrode pillar EP arranged along the second direction II. In an embodiment, the first access lines AC1 may be word lines, and the second access lines AC2 may be bit lines.

The second access line AC2 may include a first conductive layer 15B and a second conductive layer 16B. Here, the first conductive layer 15B and the second conductive layer 16B may include materials with different resistivities. In an embodiment, the first conductive layer 15B may include a carbon layer, and the second conductive layer 16B may include a metal such as tungsten. The second access line AC2 and the electrode pillar EP may be formed of separate layers or may be formed of one layer. In an embodiment, the first conductive layer 15A and the first conductive layer 15B may be combined into a single layer, and the second conductive layer 16A and the second conductive layer 16B may be combined into a single layer. In an embodiment, the first conductive layer 15A and the first conductive layer 15B may be fabricated using the same manufacturing process, and the second conductive layer 16A and the second conductive layer 16B may be fabricated using the same manufacturing process.

The first air gaps AG1 may be positioned along both edges of the stack structure STK in the second direction II. The first air gaps AG1 may be positioned to correspond to the first insulating layers 11 and extend in the first direction I along a sidewall of the stack structure STK. For example, the first air gaps AG1 may be positioned at substantially the same level as the first insulating layers 11 in the third direction III. Specifically, a top surface of the first air gap AG1 may be substantially coplanar with a top surface of a corresponding one of the first insulating layers 11, or a bottom surface of the first air gap AG1 may be substantially coplanar with a bottom surface of the corresponding one of the first insulating layers 11, or both. In the third direction III, each of the first air gaps AG1 may be positioned between an adjacent pair of first access lines AC1, and may be positioned between an adjacent pair of second insulating layers 12.

Each of the first sealing layers S1 may be formed on a sidewall of a corresponding one of the first insulating layers 11, and may define a corresponding one of the first air gaps AG1. In an embodiment, the first air gap AG1 may be positioned in the first sealing layer S1. In this case, the first air gap AG1 may be an empty space in the first sealing layer S1. In an embodiment, the first air gap AG1 may be positioned between the first sealing layer S1 and the first insulating layer 11 at the same level in the third direction III. In this case, the first air gap AG1 may be defined by a sidewall of the first sealing layer S1 and a sidewall of the first insulating layer 11. The first sealing layer S1 may be in contact with the insulating layer 17. In an embodiment, the first sealing layer S1 and the insulating layer 17 may be combined into a single layer, and a portion protruding from a sidewall of the insulating layer 17 may be the first sealing layer S1.

The second air gaps AG2 may be positioned to correspond to the first insulating layers 11 in the third direction III, and may surround the electrode pillar EP. In an embodiment, the second air gap AG2 may have a ring shape surrounding a sidewall of the electrode pillar EP. In the third direction III, each of the second air gaps AG2 may be positioned between an adjacent pair of first access lines AC1, and may be positioned between an adjacent pair of second insulating layers 12. In the third direction III, each of the second air gaps AG2 may be positioned at the same level as corresponding first air gaps AG1 that are positioned along both edges of the stack structure STK in the second direction II.

The second sealing layers S2 may be formed on sidewalls of the first insulating layers 11, and may have a ring shape surrounding the electrode pillar EP. The second air gaps AG2 may be defined by the second sealing layers S2. In an embodiment, the second air gap AG2 may be positioned in the second sealing layer S2. In this case, the second air gap AG2 may be an empty space in the second sealing layer S2. In an embodiment, the second air gap AG2 may be positioned between the second sealing layer S2 and the first insulating layer 11 at the same level in the third direction III. In this case, the second air gap AG2 may be defined by a sidewall of the second sealing layer S2 and the sidewall of the first insulating layer 11. The second sealing layer S2 may be in contact with the variable resistance layer 14.

In the stack structure STK described above, a plurality of memory cells MC may be positioned in regions where the first access lines AC1 cross the second access lines AC2. Multiple memory cells MC may be stacked along the electrode pillar EP. At least one of the first air gaps AG1 and the second air gaps AG2 may be positioned between the stacked multiple memory cells MC. At least one of the first air gaps AG1 and the second air gaps AG2 may be positioned between the stacked first access lines AC1. Therefore, a parasitic capacitance between the stacked first access lines AC1 may be reduced.

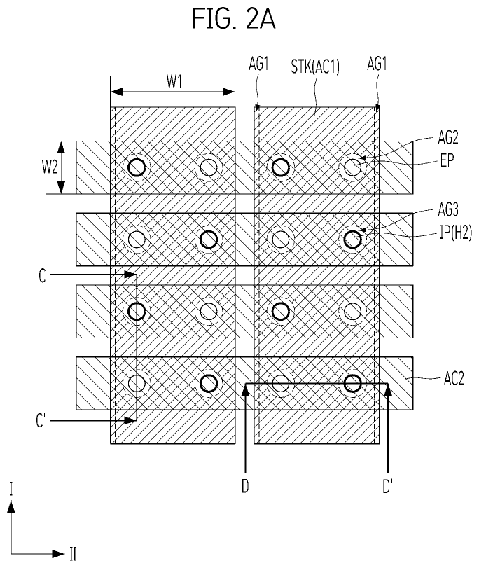

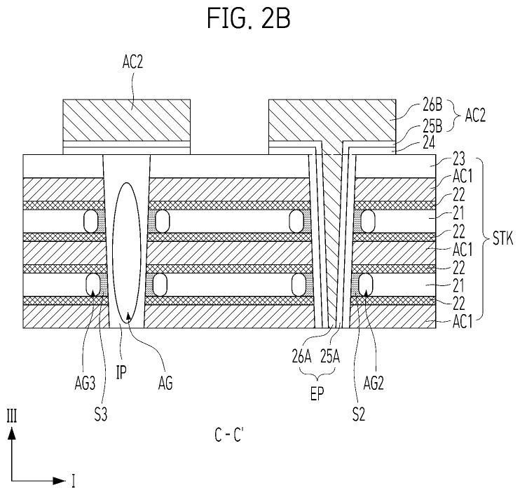

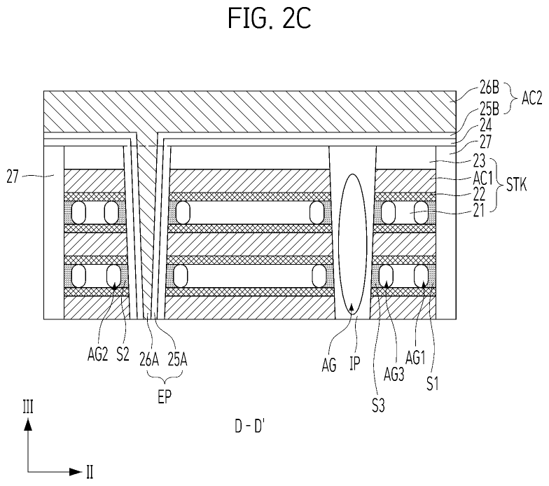

FIGS. 2A to 2C illustrate a structure of a semiconductor device according to another embodiment of the present disclosure. FIG. 2A is a plan view, FIG. 2B is a cross-sectional view taken along line C-C′ of FIG. 2A, and FIG. 2C is a cross-sectional view taken along line D-D′ of FIG. 2A. Hereinafter, the description overlapping content described above may be omitted.

Referring to FIGS. 2A to 2C, the semiconductor device may include first access lines AC1, second access lines AC2, electrode pillars EP, and insulating pillars IP. The semiconductor device may further include at least one of first insulating layers 21, second insulating layers 22, a hard mask 23, a variable resistance layer 24, first air gaps AG1, second air gaps AG2, third air gaps AG3, air gaps AG, first sealing layers S1, second sealing layers S2, and third sealing layers S3.

For illustrative convenience, the embodiment will be described with a specific focus on one of stack structures STK included in the semiconductor device.

A stack structure STK may include first access lines AC1 and first insulating layers 21 that are alternately stacked in the third direction III. The stack structure STK may further include second insulating layers 22, each of which is positioned between each of the first access lines AC1 and its corresponding one of the first insulating layers 21 in the third direction III. The first insulating layer 21 may include a material with a dielectric constant lower than that of the second insulating layer 22. The stack structure STK may further include the hard mask 23 disposed at the top of the stack structure STK.

The stack structure STK may extend in the first direction I. Insulating layers 27 may be positioned between stack structures STK arranged in parallel in the second direction II. Therefore, the stack structures STK and the insulating layers 27 may be alternately arranged along the second direction II. The stack structure STK may have a first width W1 in the second direction II.

A plurality of electrode pillars EP may be arranged both in the first direction I and the second direction II, and may extend, in the third direction III, through the stack structure STK. An electrode pillar EP may include a first conductive layer 25A and a second conductive layer 26A. Here, the first conductive layer 25A and the second conductive layer 26A may include materials with different resistivities.

The variable resistance layer 24 may surround a sidewall of the electrode pillar EP. The variable resistance layer 24 may be positioned between the electrode pillar EP and the stack structure STK that includes the first access lines AC1, the second insulating layers 22, and the first insulating layers 21.

A plurality of insulating pillars IP may extend, in the third direction III, through the stack structure STK. The plurality of insulating pillars IP and the plurality of electrode pillars EP may be alternately arranged along the first direction I and the second direction II. At least one insulating pillar IP among the plurality of insulating pillars IP may include an air gap AG therein. The variable resistance layer 14 may cover and be in contact with an upper surface of the insulating pillar IP.

The second access lines AC2 may be positioned on the stack structures STK, and may be arranged in parallel in the first direction I. Each of the second access lines AC2 may extend in the second direction II. The second access lines AC2 may be connected to the plurality of electrode pillars EP and the plurality of insulating pillars IP. In an embodiment, the first access lines AC1 may be word lines, and the second access lines AC2 may be bit lines.

The first access line AC1 and the second access line AC2 may have different widths. As described above, the first access line AC1 may have the first width W1 in the second direction II, and the second access line AC2 may have a second width W2 in the first direction I, wherein the first width W1 may be greater than the second width W2. The second access line AC2 may include a first conductive layer 25B and a second conductive layer 26B. Here, the first conductive layer 25B and the second conductive layer 26B may include materials with different resistivities.

The first air gaps AG1 may be positioned at substantially the same level as the first insulating layers 21 in the third direction III, and may extend in the first direction I along a sidewall of the stack structure STK. The first sealing layers S1 may be formed on a sidewall of the first insulating layers 21, and may define the first air gaps AG1.

The second air gaps AG2 may be positioned to correspond to the first insulating layers 21. For example, the second air gaps AG2 may be positioned at substantially the same level as the first insulating layers 21 in the third direction III, and may have a ring shape surrounding the electrode pillar EP. The second sealing layers S2 may be formed on sidewalls of the first insulating layers 21, and may have a ring shape surrounding the electrode pillar EP. The second air gaps AG2 may be defined by the second sealing layers S2.

The third air gaps AG3 may be positioned at substantially the same level as the first insulating layers 21 in the third direction III, and may surround the insulating pillar IP. In an embodiment, the third air gap AG3 may have a ring shape surrounding a sidewall of the insulating pillar IP. In the third direction III, each of the third air gaps AG3 may be positioned between two adjacent first access lines AC1, and may be positioned between two adjacent second insulating layers 22. The third air gap AG3 may be positioned at the same level as the first air gap AG1 and the second air gap AG2 in the third direction III.

The third sealing layers S3 may be formed on sidewalls of the first insulating layers 21, and may have a ring shape surrounding the insulating pillar IP. The third air gaps AG3 may be defined by the third sealing layers S3. In an embodiment, the third air gap AG3 may be positioned in the third sealing layer S3. In this case, the third air gap AG3 may be an empty space in the third sealing layer S3. In an embodiment, the third air gap AG3 may be positioned between the third sealing layer S3 and the first insulating layer 21 at the same level in the third direction III. In this case, the third air gap AG3 may be defined by a sidewall of the third sealing layer S3 and the sidewall of the first insulating layer 21. The third sealing layer S3 may be in contact with the insulating pillar IP.

In the structure described above, the insulating pillars IP may be positioned between the electrode pillars EP in both the first direction I and the second direction II. At least one insulating pillar IP among the insulating pillars IP may include the air gap AG therein. At least one of the first air gaps AG1, the second air gaps AG2, and the third air gaps AG3 may be positioned between the stacked first access lines AC1. Therefore, a parasitic capacitance between the stacked first access lines AC1 may be reduced.

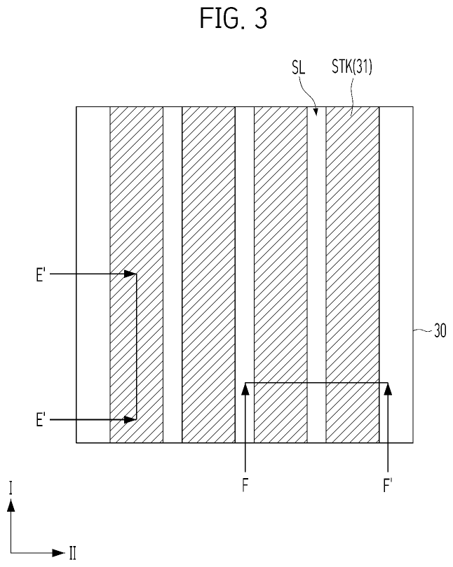

FIGS. 3, 4A, 4B, 5, 6A, 6B, 7A, 7B, 8, 9A, 9B, 10A, 10B, 11, 12A, and 12B illustrate a method of manufacturing a semiconductor device according to an embodiment of the present disclosure. Hereinafter, the description overlapping content described above may be omitted.

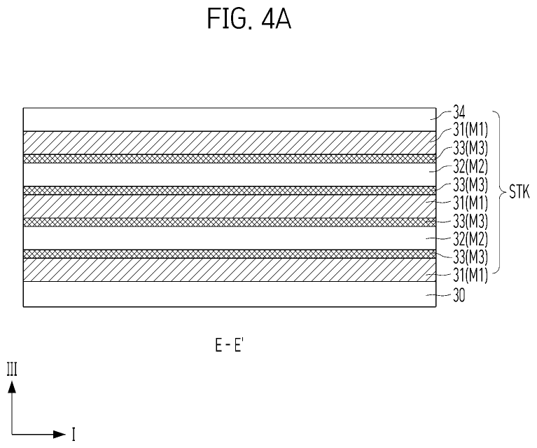

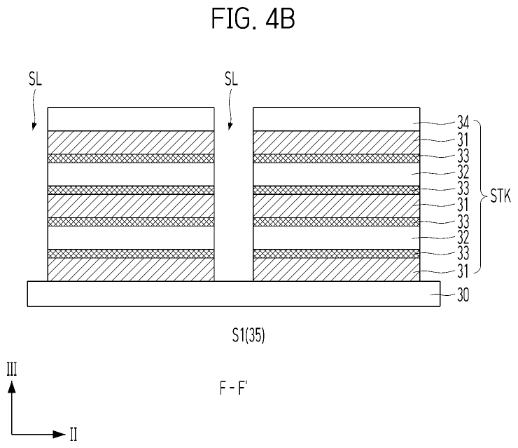

FIG. 3 is a plan view, FIG. 4A is a cross-sectional view taken along line E-E′ of FIG. 3, and FIG. 4B is a cross-sectional view taken along line F-F′ of FIG. 3.

Referring to FIGS. 3, 4A, and 4B, first material layers M1 and second material layers M2 may be alternately formed on a base 30 in the third direction III. The base 30 may include a lower structure such as a substrate and a peripheral circuit. In an embodiment, the peripheral circuit and an interlayer insulating layer may be formed on the substrate, and the first and second material layers M1 and M2 may be formed on the interlayer insulating layer. The first material layers M1 may be used for forming access lines, and may include a sacrificial material such as a nitride, or alternatively may include a conductive material such as polysilicon or a metal. The second material layers M2 may be used for insulating stacked access lines from each other, and may include an insulating material such as an oxide or a nitride.

Subsequently, a hard mask 34 may be formed on a stack of the first and second material layers M1 and M2, and slits SL may be formed by etching the stack of the first and second material layers M1 and M2 using the hard mask 34 as an etch barrier. Through this, a plurality of stack structures STK each extending in the first direction I may be formed on the base 30. The plurality of stack structures STK may be aligned in parallel along the second direction II. Each of the slits SL may be disposed between two adjacent stack structures STK in the second direction II.

A stack structure STK may include the first material layers M1 and the second material layers M2 that are alternately stacked in the third direction III, and may further include third material layers M3, each of which is positioned between each of the first material layers M1 and its corresponding one of the second material layers M2. Here, the second material layer M2 may include a material with a dielectric constant lower than that of the third material layer M3.

In the present embodiment, the first material layer M1 may be a first access line 31, a second material layer M2 may be a first insulating layer 32, and the third material layer M3 may be a second insulating layer 33. The stack structure STK may include first access lines 31 and first insulating layers 32 that are alternately stacked in the third direction III. In order to reduce a parasitic capacitance between the stacked first access lines 31, the first insulating layers 32 may include a low dielectric constant material such as SiCOH.

The stack structure STK may further include second insulating layers 33, each of which is positioned between each of the first access lines 31 and its corresponding one of the first insulating layers 32. Here, the second insulating layer 33 may be used to enhance a physical property of the first insulating layer 32, and may include a material with hardness greater than that of the first insulating layer 32. The second insulating layer 33 may include a material with a higher etch selectivity in comparison to the first insulating layer 32, and may be used as an etch stop layer in a subsequent process. In an embodiment, the first insulating layer 32 may include an oxide such as tetra ethyl ortho silicate (TEOS), and the second insulating layer 33 may include a nitride. The stack structure STK may further include the hard mask 34.

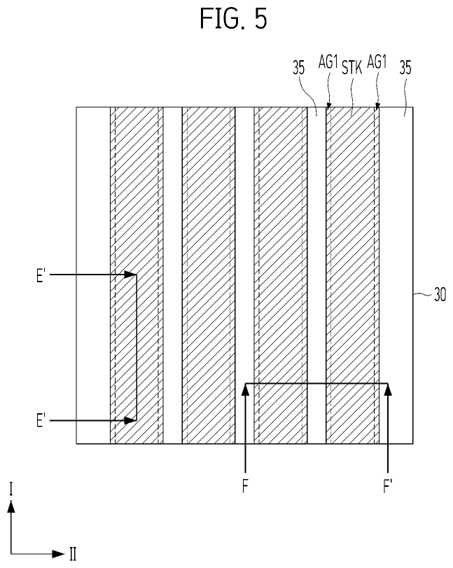

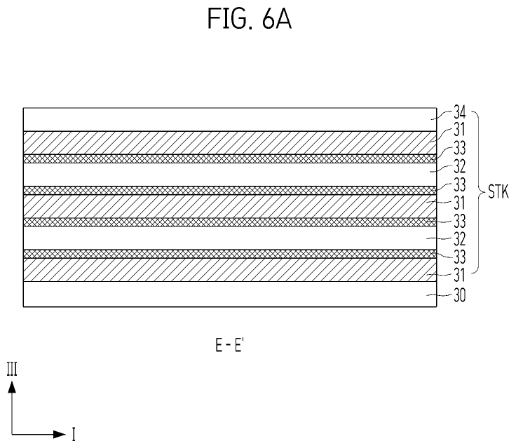

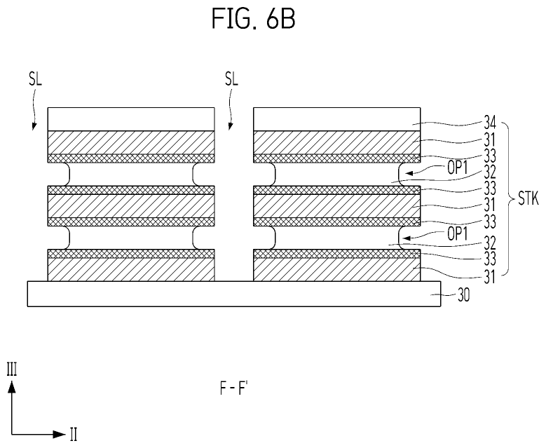

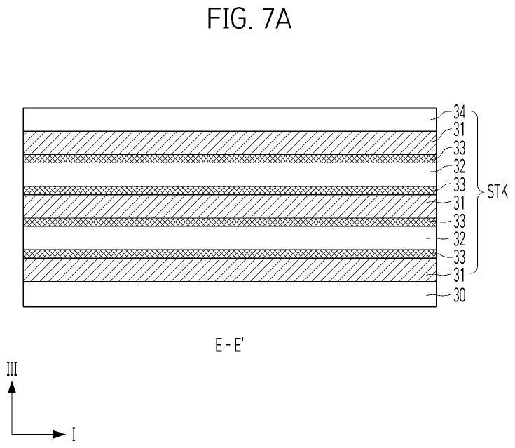

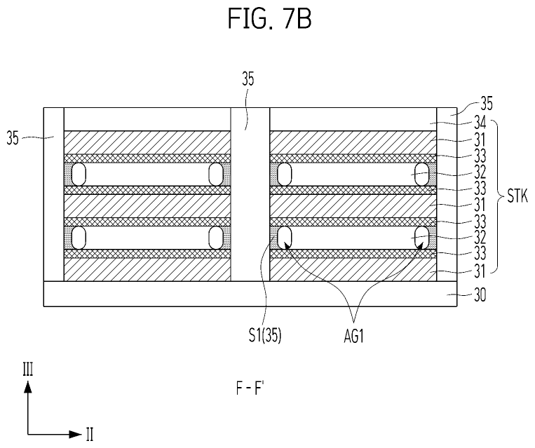

FIG. 5 is a plan view, FIGS. 6A and 7A are cross-sectional views taken along line E-E′ of FIG. 5, and FIGS. 6B and 7B are cross-sectional views taken along line F-F′ of FIG. 5.

Referring to FIG. 5, first air gaps AG1 extending along a sidewall of the stack structure STK may be formed. Here, the first air gaps AG1 may be positioned to correspond to the first insulating layers 32 in the third direction III, and may extend along the first direction I.

First, referring to FIGS. 6A and 6B, first openings OP1 may be formed by etching the first insulating layers 32 exposed through the sidewall of the stack structure STK. The first insulating layers 32 may be selectively etched through the slit SL. The first openings OP1 may extend in the first direction I along the sidewall of the stack structure STK. The first openings OP1 may be positioned between the stacked first access lines 31, and may be positioned between the second insulating layers 33, in the third direction III. The second insulating layers 33 may be partially exposed through the first openings OP1.

Subsequently, referring to FIGS. 7A and 7B, first sealing layers S1 may be formed in the first openings OP1. In an embodiment, the first sealing layers S1 may be formed by depositing an insulating material in the first openings OP1 through the slit SL. In the deposition process, the first air gaps AG1 may be formed in the first openings OP1. Here, the first air gap AG1 may be an empty space in which an insulating material is not deposited. The first air gap AG1 may be positioned inside the first sealing layer S1 or may be positioned between the first sealing layer S1 and the etched first insulating layer 32 at the same level in the third direction III. The first sealing layers S1 may include an insulating material such as an oxide.

Subsequently, an insulating layer 35 may be formed in the slit SL. When depositing an insulating material to form the first sealing layer S1, the insulating material may also be deposited to fill the slit SL. In this case, the first sealing layer S1 and the insulating layer 35 may be formed simultaneously. Alternatively, the first sealing layer S1 and the insulating layer 35 may be formed in separate processes.

For reference, when the first material layers M1 include a sacrificial material, the first material layers M1 may be replaced with the first access lines 31 through the slit SL. In an embodiment, before forming the first openings OP1 or before forming the insulating layer 35, the first material layers M1 may be replaced with the first access lines 31.

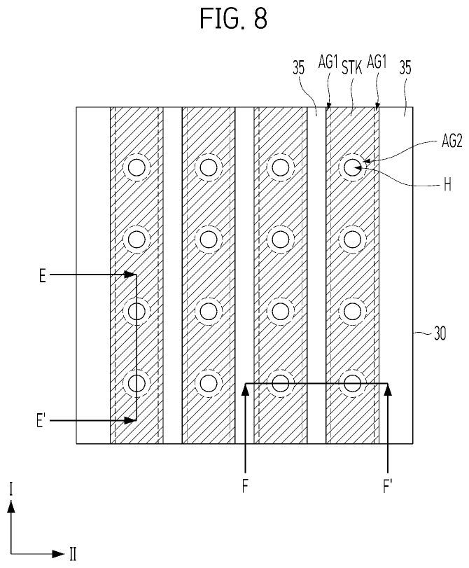

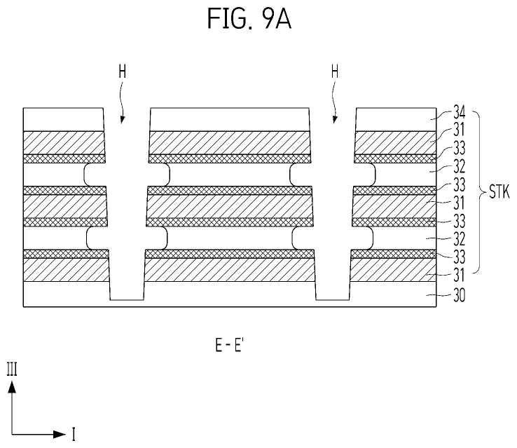

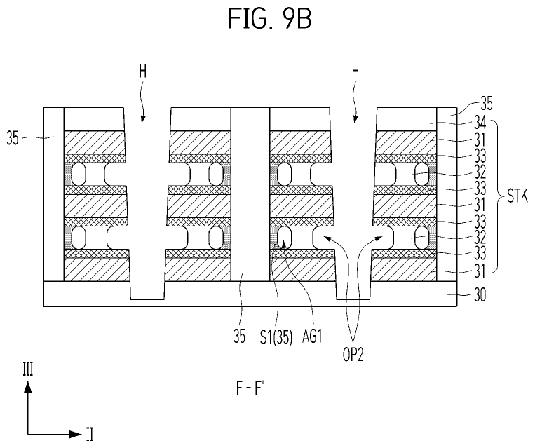

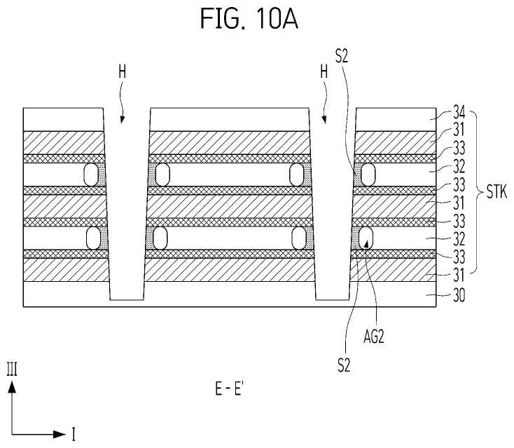

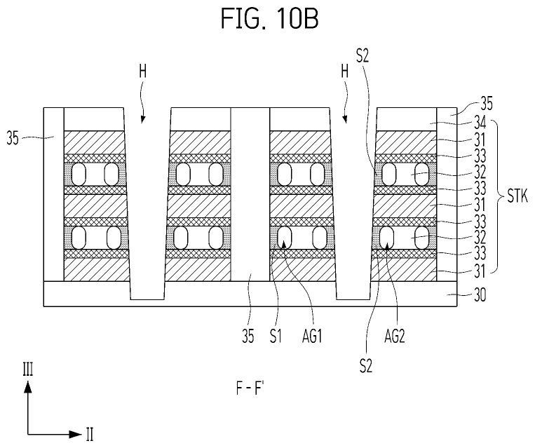

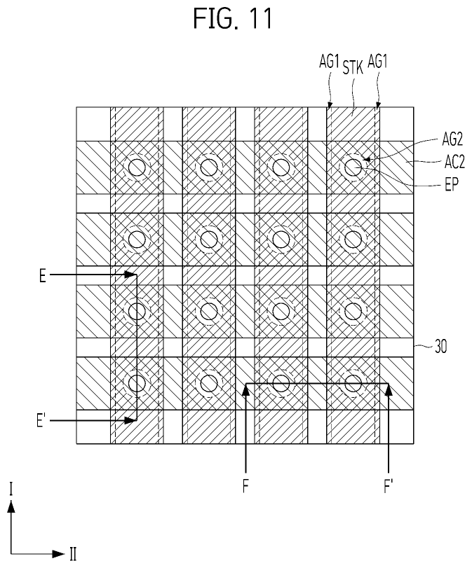

FIG. 8 is a plan view, FIGS. 9A and 10A are cross-sectional views taken along line E-E′ of FIG. 8, and FIGS. 9B and 10B are cross-sectional views taken along line F-F′ of FIG. 8.

Referring to FIG. 8, second air gaps AG2 may be formed in the stack structure STK including the first air gaps AG1. Here, the second air gaps AG2 may be positioned to correspond to the first insulating layers 32. In the semiconductor device, the second air gaps AG2 may be arranged both in the first direction I and the second direction II, and each of the second air gaps AG2 may have a ring shape, when viewed in a plan view.

First, referring to FIGS. 9A and 9B, holes H may be formed in the stack structure STK including the first air gaps AG1. The holes H may have a shape such as circular, elliptical, polygonal, or the like, when viewed in a plan view. In the stack structure STK, the holes H may be arranged in the first direction I. The holes H may extend, in the third direction III, through the stack structure STK including the first air gaps AG1.

Subsequently, second openings OP2 may be formed by selectively etching the first insulating layers 32 exposed through the holes H. The second openings OP2 may have a ring shape surrounding the holes H. In the third direction III, the second openings OP2 may be positioned between the stacked first access lines 31, and may be positioned between the second insulating layers 33.

Subsequently, referring to FIGS. 10A and 10B, second sealing layers S2 may be formed in the second openings OP2. In an embodiment, the second sealing layers S2 may be formed by depositing an insulating material in the second openings OP2 through the hole H. When depositing the insulating material to form the second sealing layers S2, the insulating material may also be deposited in the hole H. In this case, after depositing the insulating material, a deposited portion in the hole H may be etched to form the second sealing layers S2. In the deposition process, part of the second openings OP2 might not be filled with the insulating material, so that the second air gaps AG2 may be formed in the second openings OP2. Here, the second air gap AG2 may be an empty space in which the insulating material is not deposited. The second air gap AG2 may be positioned inside the second sealing layer S2, or alternatively may be positioned between the second sealing layer S2 and the first insulating layer 32. The second sealing layers S2 may include an insulating material such as an oxide.

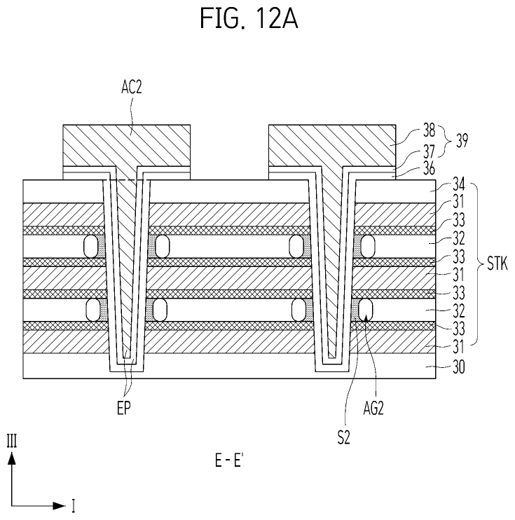

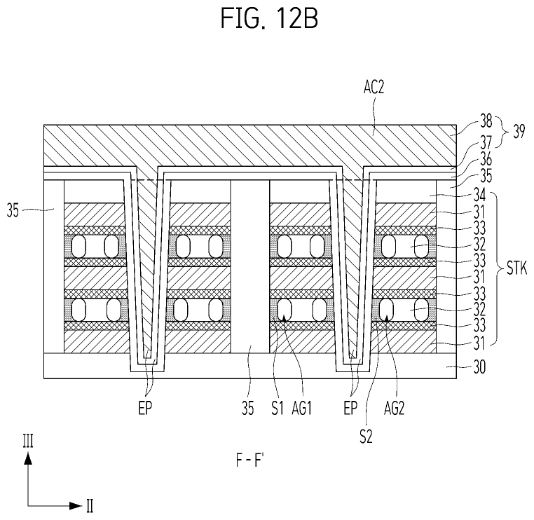

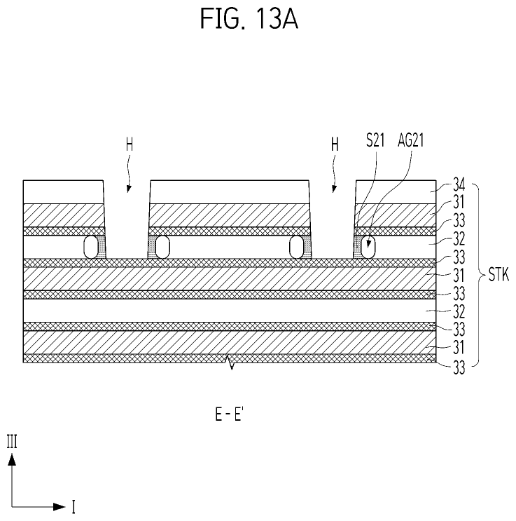

FIG. 11 is a plan view, FIG. 12A is a cross-sectional view taken along line E-E′ of FIG. 11, and FIG. 12B is a cross-sectional view taken along line F-F′ of FIG. 11.

Referring to FIGS. 11, 12A, and 12B, a variable resistance layer 36 and a conductive layer 39 may be formed. First, the variable resistance layer 36 may be formed along a profile of stack structures STK including holes H. The variable resistance layer 36 may be formed not only inside the holes H but also on the stack structures STK. The variable resistance layer 36 may be formed to partially fill the holes H. Subsequently, the conductive layer 39 may be formed on the variable resistance layer 36. The conductive layer 39 may be formed to completely fill the remaining portions of the holes H after forming the variable resistance layer 36, and the conductive layer 39 may also be formed on the stack structures STK. Here, the conductive layer 39 may include a first conductive layer 37 and a second conductive layer 38. In an embodiment, the first conductive layer 37 may include a carbon layer, and the second conductive layer 38 may include a metal such as tungsten (W).

Subsequently, the conductive layer 39 and the variable resistance layer 36 may be etched. Through this, electrode pillars EP and second access lines AC2 may be formed. Portions of the conductive layer 39 formed in the holes H may become the electrode pillars EP. The electrode pillars EP may be arranged both in the first direction I and the second direction II when viewed in a plan view. Portions of the conductive layer 39 formed on the stack structures STK may become the second access lines AC2. Each of the second access lines AC2 may extend in the second direction II. A plurality of electrode pillars EP arranged in the second direction II may be electrically connected through one second access line AC2.

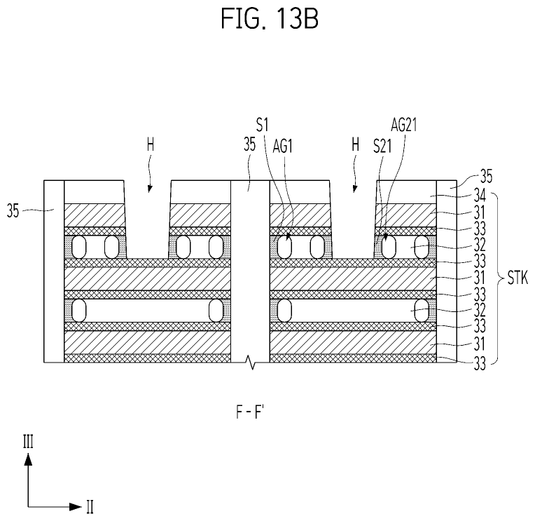

According to the manufacturing method described above, at least one of the first air gaps AG1 and the second air gaps AG2 may be formed between the stacked first access lines 31. Therefore, a parasitic capacitance between the stacked first access lines 31 may be reduced. FIGS. 13A to 15A and 13B to 15B illustrate a method of manufacturing a semiconductor device according to another embodiment of the present disclosure. FIGS. 13A, 14A, and 15A are cross-sectional views taken along line E-E′ of FIG. 8, and FIGS. 13B, 14B, and 15B are cross-sectional views taken along line F-F′ of FIG. 8. Hereinafter, the description overlapping content described above may be omitted.

Referring to FIGS. 13A and 13B, holes H may be formed by etching the stack structure STK until at least one of the first insulating layers 32 in the stack structure STK is etched. The depth of the holes H may align with a bottom surface of the aforementioned first insulating layer 32 in the stack structure STK. The holes H may be formed by etching the stack structure STK using the second insulating layer 33 beneath the aforementioned first insulating layer 32 as an etch stop layer. During the etching process, the depth of the holes H may be controlled by detecting the second insulating layer 33 beneath the aforementioned first insulating layer 32 or by using etch selectivities inherent in both the first insulating layer 32 and the second insulating layer 33. Subsequently, second openings are formed by selectively etching the aforementioned first insulating layer 32 exposed through the holes H, and second sealing layers S21 may be formed in the second openings. Each of the second sealing layers S21 may have a ring shape surrounding a corresponding one of the holes H, and a second air gap AG21 may be defined by the second sealing layer S21. The second air gap AG21 may be disposed between the second sealing layer S21 and the first insulating layer 32. Alternately, the second air gap AG21 may be formed in the second sealing layer S21.

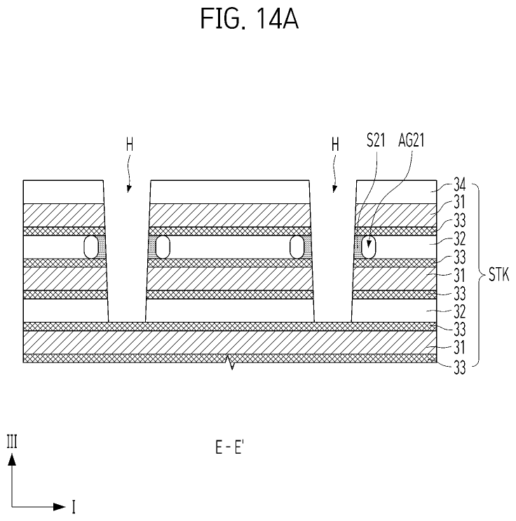

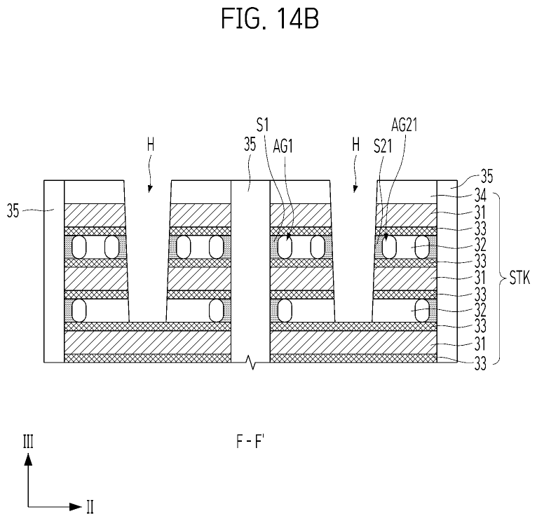

Referring to FIGS. 14A and 14B, the holes H may extend into the stack structure STK. By extending the holes H, at least one first insulating layer 32 may be additionally etched. The holes H may be extended by further etching the stack structure STK using the second insulating layer 33 beneath the additional first insulating layer 32 as an etch stop layer.

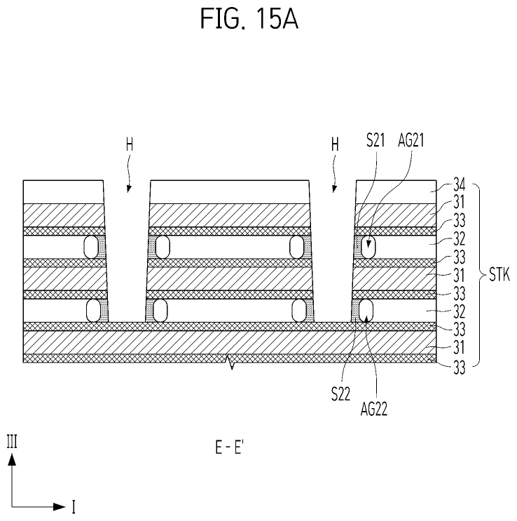

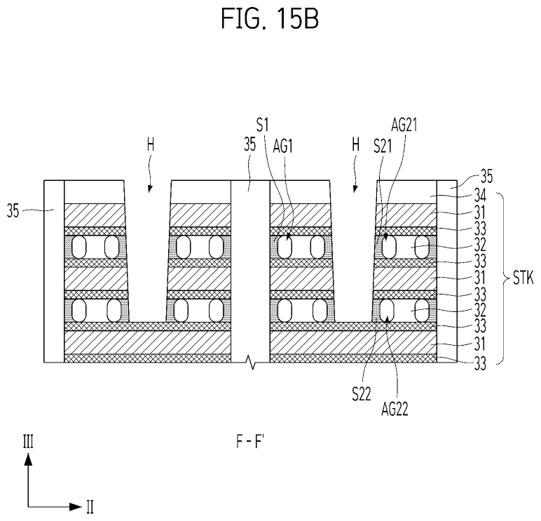

Referring to FIGS. 15A and 15B, additional second openings may be formed by selectively etching the additional first insulating layers 32 exposed through the extended holes H, and additional second sealing layers S22 may be formed in the additional second openings. The additional second sealing layer S22 may have a ring shape surrounding the extended portion of the hole H, and an additional second air gap AG22 may be defined by the second sealing layer S22. The second air gap AG22 may be disposed between the second sealing layer S22 and the additional first insulating layer 32.

Subsequently, the processes of extending the holes H, forming the additional second openings, and forming the additional second sealing layers may be repeatedly performed in a series of steps in the stack structure STK. Through the repeated processes, the second air gaps AG2 (e.g., AG21 and AG22 in FIGS. 15A and 15B) positioned to correspond to the first insulating layers 32 may be formed sequentially in the stack structure STK.

According to the manufacturing method described above, the complete formation of the entire hole H in a specific region of the stack structure STX may be formed by performing the etching process iteratively, and the second air gaps AG2 (e.g., AG21 and AG22 in FIGS. 15A and 15B) in that region may be formed by etching each of the first insulating layers 32 during each of the multiple iterations of the etching process.

When forming the second air gaps AG2 in the stack structure STK simultaneously, sizes of the second air gaps AG2 may vary according to an etching environment. Notably, the second air gaps AG2 positioned in an upper portion of the stack structure STK may tend to be formed in a relatively larger size, potentially causing the collapse of the first access lines 31 in that portion. To address this concern, the formation of the second air gaps AG2 through the multiple iterations of the etching process ensures a more uniform size of the second air gaps AG2, effectively preventing or mitigating the collapse of the first access lines 31.

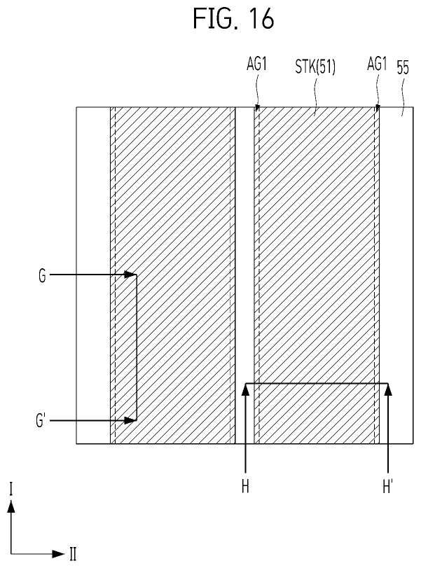

FIGS. 16, 17A, 17B, 18, 19A, 19B, 20, 21A, and 21B illustrate a method of manufacturing a semiconductor device according to another embodiment of the present disclosure. Hereinafter, the description overlapping content described above may be omitted.

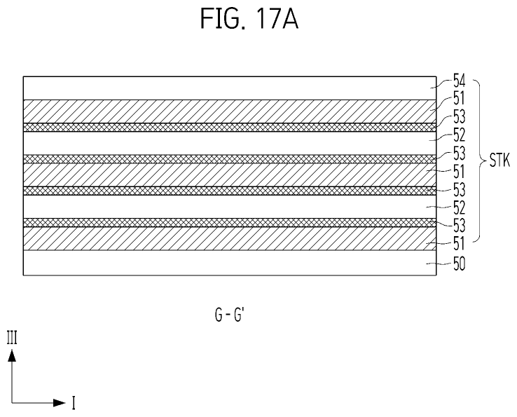

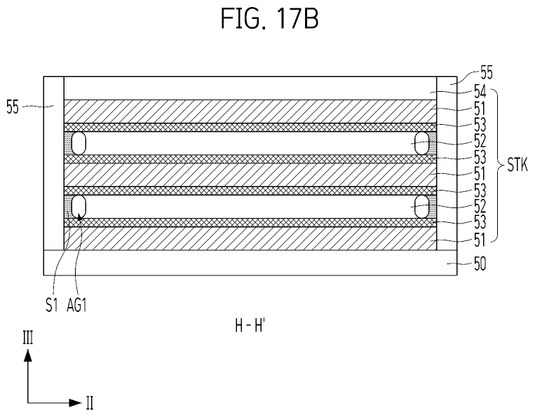

FIG. 16 is a plan view, FIG. 17A is a cross-sectional view taken along line G-G′ of FIG. 16, and FIG. 17B is a cross-sectional view taken along line H-H′ of FIG. 16.

Referring to FIGS. 16, 17A, and 17B, stack structures STK each extending in the first direction I may be formed on a base 50. The stack structures STK may be arranged in parallel in the second direction II. Each of the stack structures STK may include first access lines 51 and first insulating layers 52 that are alternately stacked in the third direction III. The stack structure STK may further include at least one of a hard mask 54 and second insulating layers 53. Each of the second insulating layers 53 is positioned between each of the first access lines 51 and its corresponding one of the first insulating layers 52.

Subsequently, openings may be formed by etching both edges of the first insulating layers 52 in the second direction II, where the both edges are exposed through both sidewalls of the stack structure STK in the second direction II. Subsequently, first sealing layers S1 may be formed in the openings. First air gaps AG1 may be defined by the first sealing layers S1. Each of the first air gaps AG1 may be disposed between each of the first sealing layers S1 and its corresponding one of the first insulating layers 52 at the same level in the third direction III. When forming the first sealing layers S1, insulating layers 55 positioned between the stack structures STK arranged in parallel in the second direction II may also be formed.

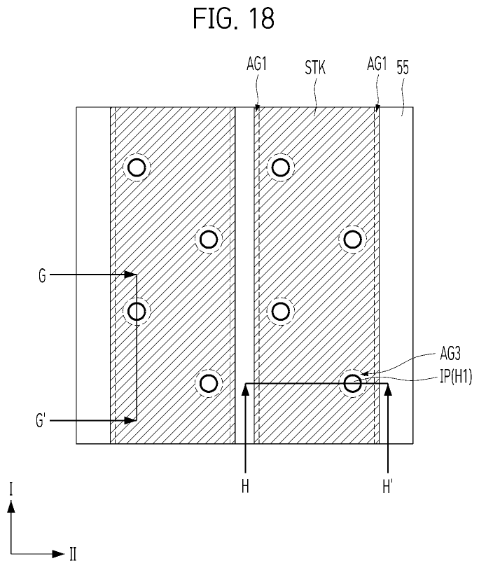

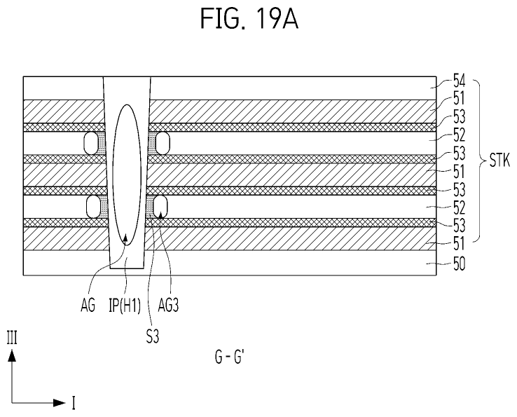

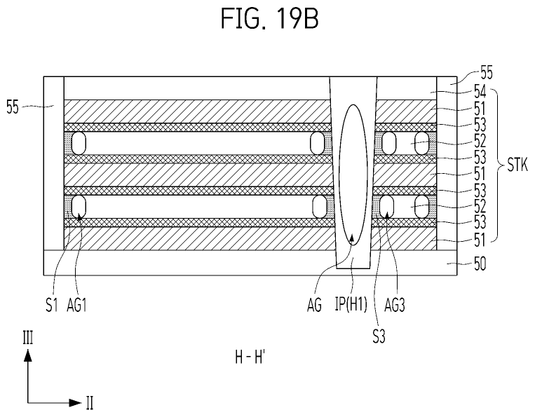

FIG. 18 is a plan view, FIG. 19A is a cross-sectional view taken along line G-G′ of FIG. 18, and FIG. 19B is a cross-sectional view taken along line H-H′ of FIG. 18.

Referring to FIGS. 18, 19A, and 19B, first holes H1 may be formed in the stack structure STK. The first holes H1 may be arranged in a zigzag shape in the stack structure STK when viewed in a plan view. The first holes H1 may extend, in the third direction III, through the stack structure STK.

Subsequently, openings may be formed by selectively etching the first insulating layers 52 exposed through the first holes H. Subsequently, third sealing layers S3 may be formed in the openings. Third air gaps AG3 may be defined by the third sealing layers S3. The third air gap AG3 may be an empty space in the third sealing layer S3. Each of the third air gaps AG3 may be disposed between each of the third sealing layers S3 and its corresponding one of the first insulating layers 52 at the same level in the third direction III.

Subsequently, insulating pillars IP may be formed in the first holes H1 by depositing an insulating material. At least one pillar IP among the insulating pillars IP may include an air gap AG therein. When depositing an insulating material to form the third sealing layers S3, the insulating material may also be deposited in the first holes H1, and thus the third sealing layers S3 and the insulating pillars IP may be formed simultaneously. Alternatively, the third sealing layers S3 and the insulating pillars IP may be formed in separate processes.

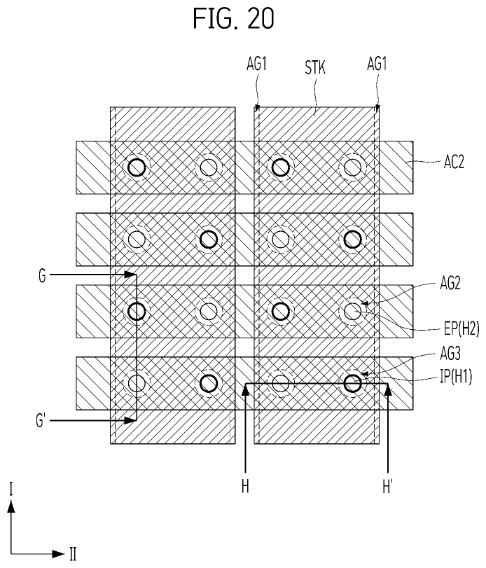

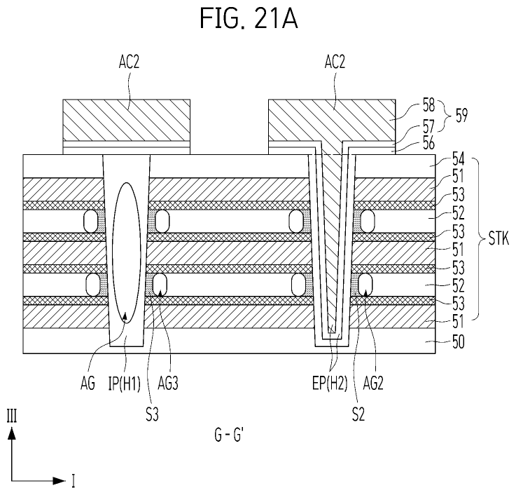

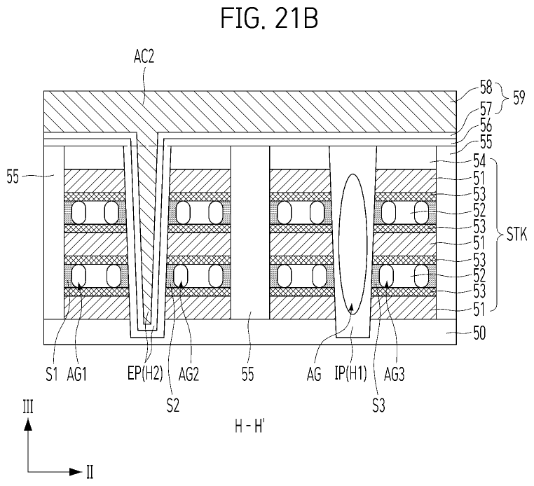

FIG. 20 is a plan view, FIG. 21A is a cross-sectional view taken along line G-G′ of FIG. 20, and FIG. 21B is a cross-sectional view taken along line H-H′ of FIG. 20.

Referring to FIGS. 20, 21A, and 21B, second holes H2 may be formed in the stack structure STK. The second holes H2 may be arranged in a zigzag shape in the stack structure STK when viewed in a plan view. The second holes H2 may extend, in the third direction III, through the stack structure STK. The first holes H1 and the second holes H2 may be alternately arranged in the first direction I and the second direction II.

Subsequently, openings may be formed by selectively etching the first insulating layers 52 exposed through the second holes H2. Subsequently, second sealing layers S2 may be formed in the openings. Second air gaps AG2 positioned in the openings may be defined by the second sealing layers S2. The second air gap AG2 may be an empty space in the second sealing layer S2. Each of the second air gaps AG2 may be disposed between each of the second sealing layers S2 and its corresponding one of the first insulating layer 52 at the same level in the third direction III.

Subsequently, a variable resistance layer 56 may be formed in the second holes H2. The variable resistance layer 56 may be formed along inner surfaces of the second holes H2 and upper surfaces of stack structures STK. The variable resistance layer 56 may be formed to partially fill the second holes H2.

Subsequently, a conductive layer 59 may be formed on the variable resistance layer 56. The conductive layer 59 may be formed to completely fill the remaining portion of the second holes H2 after forming the variable resistance layer 56, and the conductive layer 59 may also be formed on the upper surface of the stack structures STK. The variable resistance layer 56 and the conductive layer 59 may be also formed on upper surfaces of the insulating pillars IP and the insulating layers 55 positioned between the stack structures STK arranged in parallel in the second direction II. Here, the conductive layer 59 may include a first conductive layer 57 and a second conductive layer 58. In an embodiment, the first conductive layer 57 may include a carbon layer, and the second conductive layer 58 may include a metal such as tungsten (W).

Subsequently, the conductive layer 59 and the variable resistance layer 56 may be etched. Through this, the electrode pillars EP and the second access lines AC2 may be formed. A portion of the conductive layer 59 formed in the second hole H2 may become the electrode pillar EP. The electrode pillar EP may be positioned between two adjacent insulating pillars IP in either the first direction I or the second direction II. Therefore, the electrode pillars EP and the insulating pillars IP may be alternately arranged in the first direction I and the second direction II. A portion of the conductive layer 59 formed on the stack structure STK may become the second access line AC2. The second access line AC2 may extend in the second direction II. Multiple electrode pillars EP and multiple insulating pillars IP arranged in the second direction II may be aligned with a specific second access line AC2, and may be connected to the specific second access line AC2. According to the manufacturing method described above, the insulating pillar IP including the air gap AG and extending through the stack structure STK may be formed. At least one of the first air gaps AG1, the second air gaps AG2, and the third air gaps AG3 may be formed between the stacked first access lines 51. Therefore, a parasitic capacitance between the stacked first access lines 51 may be reduced.

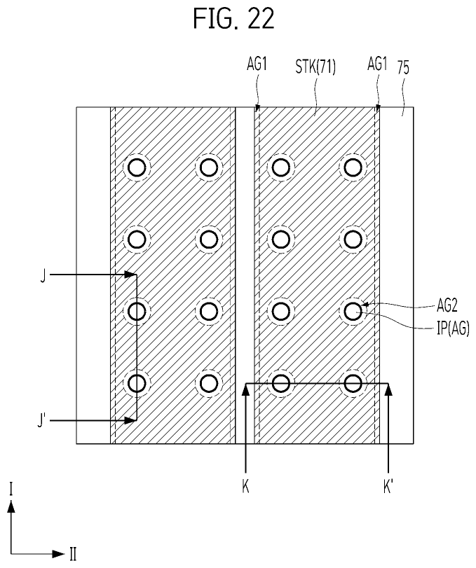

FIGS. 22, 23A, 23B, 24, 25A, 25B, 26A, and 26B illustrate a method of manufacturing a semiconductor device according to another embodiment of the present disclosure. Hereinafter, the description overlapping content described above may be omitted.

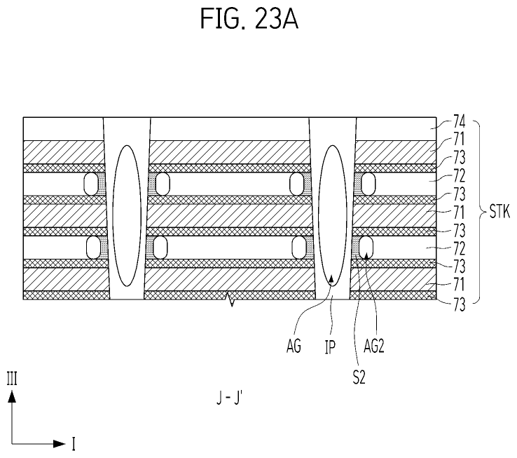

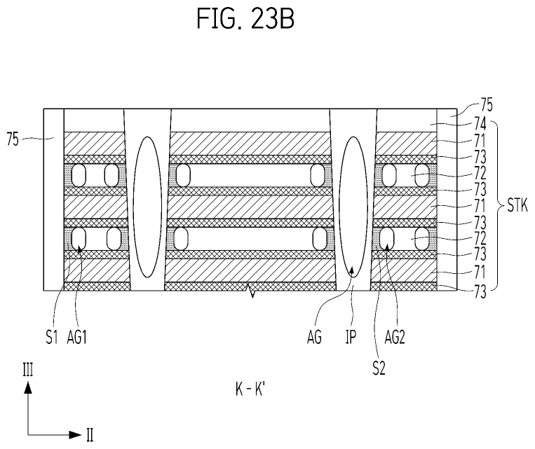

FIG. 22 is a plan view, FIG. 23A is a cross-sectional view taken along line J-J′ of FIG. 22, and FIG. 23B is a cross-sectional view taken along line K-K′ of FIG. 22.

Referring to FIGS. 22, 23A, and 23B, stack structures STK extending in the first direction I may be formed to be arranged in parallel in the second direction II. Each of the stack structures STK may include first access lines 71 and first insulating layers 72 that are alternately stacked in the third direction III. The stack structure STK may further include at least one of a hard mask 74 and second insulating layers 73. Each of the second insulating layers 73 may be positioned between each of the first access lines 71 and its corresponding one of the first insulating layers 72 in the third direction III.

Subsequently, openings may be formed by etching both edges of the first insulating layers 72 in the second direction III, where the both edges are exposed through sidewalls of the stack structure STK in the second direction II. Subsequently, first sealing layers S1 may be formed in the openings. First air gaps AG1 may be defined by the first sealing layers S1. The first air gap AG1 may be an empty space in the first sealing layer S1. Each of the first air gaps AG1 may be disposed between each of the first sealing layers S1 and its corresponding one of the first insulating layers 72 at the same level in the third direction III.

When forming the first sealing layers S1, insulating layers 75 may be formed between the stack structures STK arranged in the second direction II.

Subsequently, holes H may be formed in the stack structure STK. The holes H may be arranged in the first direction I and the second direction II. The holes H may extend, in the third direction III, through the stack structure STK.

Subsequently, openings may be formed by selectively etching the first insulating layers 72 exposed through the holes H. Subsequently, second sealing layers S2 may be formed in the openings. Second air gaps AG2 may be defined by the second sealing layers S2. The second air gap AG2 may be an empty space in the second sealing layer S2. Each of the second air gaps AG2 may be disposed between each of the second sealing layers S2 and its corresponding one of the first insulating layers 72 at the same level in the third direction III. Subsequently, insulating pillars IP may be formed in the holes H. The insulating pillars IP may be arranged in the first direction I and the second direction II. At least one insulating pillar IP among the insulating pillars IP may include an air gap AG therein. When depositing an insulating material to form the second sealing layers S2, the insulating material may also be deposited in the holes H, and thus the second sealing layers S2 and the insulating pillars IP may be formed simultaneously. Alternatively, the second sealing layers S2 and the insulating pillars IP may be formed in separate processes.

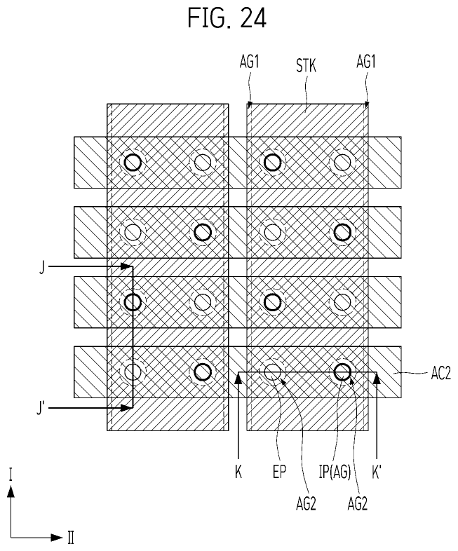

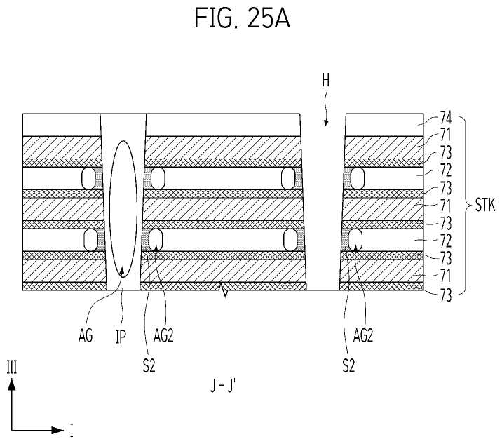

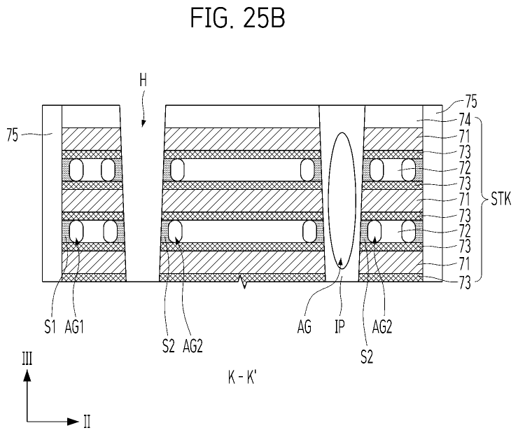

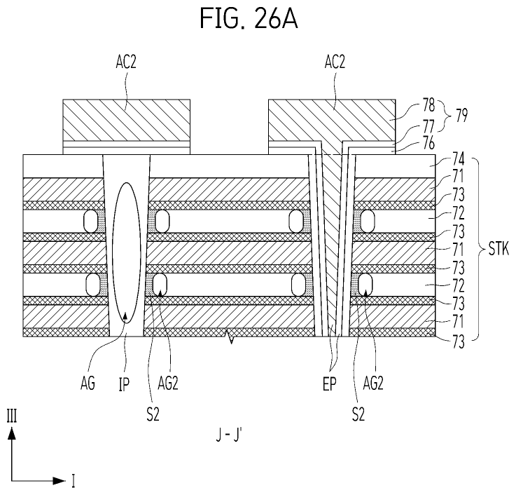

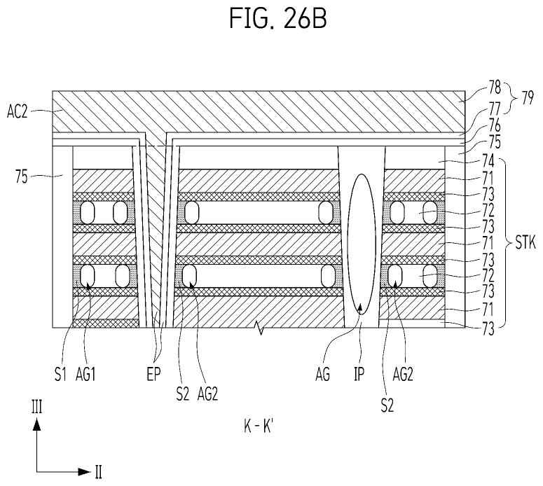

FIG. 24 is a plan view, FIGS. 25A and 26A are cross-sectional views taken along line J-J′ of FIG. 24, and FIGS. 25B and 26B are cross-sectional views taken along line K-K′ of FIG. 24.

Referring to FIG. 24, some of the insulating pillars IP may be replaced with electrode pillars EP. First, referring to FIGS. 25A and 25B, at least one insulating pillar IP among the insulating pillars IP may be removed. Through this, at least one hole H among the holes H may be reopened. In an embodiment, to reopen at least one hole H, a mask pattern exposing at least one insulating pillar IP and covering the remaining insulating pillars IP may be formed on the stack structure STK, and then, the insulating material in the insulating pillars IP may be removed using the mask pattern as an etch barrier.

Subsequently, referring to FIGS. 26A and 26B, a variable resistance layer 76 may be formed in the reopened holes H. The variable resistance layer 76 may be formed along inner surfaces of the reopened holes H and upper surfaces of the stack structures STK. The variable resistance layer 76 may be formed to partially fill the reopened holes H.

Subsequently, a conductive layer 79 may be formed on the variable resistance layer 76. The conductive layer 79 may be formed to completely fill the remaining portions of the reopened holes H after forming the variable resistance layer 76, and the conductive layer 79 may also be formed over the upper surfaces of the stack structures STK. The variable resistance layer 76 and the conductive layer 79 may be also formed over upper surfaces of the insulating pillars IP and the insulating layers 75 formed between the stack structures STK arranged in the second direction II. Here, the conductive layer 79 may include a first conductive layer 77 and a second conductive layer 78. In an embodiment, the first conductive layer 77 may include a carbon layer, and the second conductive layer 78 may include a metal such as tungsten (W).

Subsequently, the conductive layer 79 and the variable resistance layer 76 may be etched. Through this, the electrode pillars EP and the second access lines AC2 may be formed. The second access lines AC2 may extend in the second direction II. The second access lines AC2 extending in the second direction II may be arranged in parallel in the first direction I. Multiple electrode pillars EP and multiple insulating pillars IP arranged in the second direction II may be aligned with a specific second access line AC2, and may be connected to the specific second access line AC2.

According to the manufacturing method described above, the insulating pillar IP including the air gap AG may be formed. At least one of the first air gaps AG1 and the second air gaps AG2 may be formed between the stacked first access lines 71. Therefore, by forming the insulating pillar IP including the air gap AG and at least one of the first air gaps AG1 and the second air gaps AG2 between the stacked first access lines 71, a parasitic capacitance between the stacked first access lines 71 may be reduced.

Although embodiments according to the technical spirit of the present disclosure have been described with reference to the accompanying drawings, this is only for describing an embodiment according to the concept of the present disclosure, and the present disclosure is not limited to the above-described embodiments. Within the scope of the technical spirit of the present disclosure, various forms of substitution, modification, change, and combination of the embodiments will be possible by those skilled in the art to which the present disclosure belongs, and these also belong to the scope of the present disclosure.

What is claimed is:

1. A semiconductor device comprising:
a stack structure including first access lines and first insulating layers that are alternately stacked, the stack structure extending in a first direction;
first air gaps positioned to correspond to the first insulating layers, the first air gaps each extending in the first direction along a sidewall of the stack structure;
an electrode pillar extending through the stack structure; and
second air gaps positioned to correspond to the first insulating layers and surrounding the electrode pillar.

2. The semiconductor device of claim 1, wherein the first access lines and the first insulating layers are alternately stacked in a third direction, and the first air gaps are positioned at the substantially same level as the first insulating layers in the third direction to correspond to the first insulating layers, and
wherein the second air gaps are positioned at the substantially same level as the first insulating layers in the third direction to correspond to the first insulating layers.

3. The semiconductor device of claim 1, further comprising:
a first sealing layer positioned on a sidewall of a corresponding one of the first insulating layers and defining a corresponding one of the first air gaps with the corresponding first insulating layer.

4. The semiconductor device of claim 1, further comprising:
a second sealing layer surrounding a sidewall of the electrode pillar and defining a corresponding one of the second air gaps with a corresponding one of the first insulating layers.

5. The semiconductor device of claim 1, further comprising:
an insulating pillar extending through the stack structure.

6. The semiconductor device of claim 5, further comprising:
third air gaps positioned at substantially the same level as the first insulating layers in the third direction to correspond to the first insulating layers, and a corresponding one of the third air gaps surrounding the insulating pillar.

7. The semiconductor device of claim 6, further comprising:
a third sealing layer surrounding a sidewall of the insulating pillar and defining a corresponding one of the third air gaps with a corresponding one of the first insulating layers.

8. The semiconductor device of claim 5, wherein the insulating pillar includes an air gap therein.

9. The semiconductor device of claim 1, further comprising:
a variable resistance layer surrounding a sidewall of the electrode pillar.

10. The semiconductor device of claim 9, wherein the variable resistance layer maintains a phase after a program operation has been performed.

11. The semiconductor device of claim 1, further comprising:
a second access line connected to the electrode pillar and extending in a second direction crossing the first direction.

12. The semiconductor device of claim 1, wherein the stack structure further includes second insulating layers each positioned between a corresponding one of the first access lines and a corresponding one of the first insulating layers, and
wherein the first insulating layers include a material having a dielectric constant lower than that of the second insulating layers.

13. The semiconductor device of claim 12, wherein the first air gaps are each positioned between an adjacent pair of the second insulating layers in the third direction.

14. The semiconductor device of claim 12, wherein the second air gaps are each positioned between an adjacent pair of the second insulating layers in the third direction.

15. A semiconductor device comprising:
first access lines extending in a first direction;
second access lines extending in a second direction that crosses the first direction;
electrode pillars extending through the first access lines and connected to the second access lines; and
insulating pillars extending through the first access lines and connected to the second access lines, at least one of the insulating pillars including an air gap therein.

16. The semiconductor device of claim 15, wherein the electrode pillars and the insulating pillars are alternately arranged along the first direction and the second direction.

17. The semiconductor device of claim 15, wherein the first access lines are stacked in a third direction substantially perpendicular to the first and second directions, the device further comprising:
first air gaps positioned between the stacked first access lines and extending along the first direction.

18. The semiconductor device of claim 15, wherein the first access lines are stacked in a third direction substantially perpendicular to the first and second directions, the device further comprising:
second air gaps positioned between the stacked first access lines, each of the second air gaps surrounding a sidewall of a corresponding one of the electrode pillars.

19. The semiconductor device of claim 15, wherein the first access lines are stacked in a third direction substantially perpendicular to the first and second directions, the device further comprising:
third air gaps positioned between the stacked first access lines, each of the third air gaps surrounding a sidewall of a corresponding one of the insulating pillars.

20. The semiconductor device of claim 15, further comprising:
a variable resistance layer surrounding a sidewall of a corresponding one of the electrode pillars.

21. The semiconductor device of claim 20, wherein the variable resistance layer maintains a phase after a program operation has been performed.

22. A method of manufacturing a semiconductor device, the method comprising:
forming a stack structure including first access lines and first insulating layers that are alternately stacked, the stack structure extending in a first direction;
forming first openings by selectively etching the first insulating layers exposed through a sidewall of the stack structure;
forming first sealing layers defining first air gaps positioned in the first openings, the first air gaps extending in the first direction;
forming first holes extending through at least one of the first insulating layers in the stack structure;
forming second openings by selectively etching the at least one of the first insulating layers that is exposed through the first holes;
forming second sealing layers defining second air gaps positioned in the second openings; and
forming electrode pillars in the first holes.

23. The method of claim 22, further comprising:
forming a second access line that extends in a second direction crossing the first direction and is connected to the electrode pillars.

24. The method of claim 22, wherein the stack structure further includes second insulating layers each positioned between a corresponding one of the first access lines and a corresponding one of the first insulating layers, and
wherein the first insulating layers have a dielectric constant lower than that of the second insulating layers.

25. The method of claim 24, wherein the second insulating layers are partially exposed through the first openings.

26. The method of claim 22, further comprising:
forming a variable resistance layer in each of the first holes.

27. The method of claim 22, further comprising:
extending the first holes into the stack structure to further expose additional one or more of the first insulating layers;
forming additional second openings by selectively etching the additional first insulating layers that are exposed through the extended first holes; and
forming additional second sealing layers in the additional second openings, the additional sealing layers defining additional second air gaps,
wherein processes of extending the first holes, forming the additional second openings, and forming the additional second sealing layers are repeatedly performed.

28. The method of claim 22, further comprising:
forming second holes extending through the stack structure; and
forming insulating pillars in the second holes.

29. The method of claim 28, before forming the insulating pillars, further comprising:
forming third openings by selectively etching the first insulating layers exposed through the second holes; and
forming third sealing layers defining third air gaps positioned in the third openings.

30. The method of claim 28, wherein at least one of the insulating pillars includes an air gap therein.

31. The method of claim 28, further comprising:
forming a second access line that extends in a second direction crossing the first direction and is connected to one or more of the electrode pillars and one or more of the insulating pillars.

32. The method of claim 22, wherein forming the electrode pillars comprises:
forming insulating pillars in the first holes;
reopening some of the first holes by removing some of the insulating pillars; and
forming the electrode pillars in the reopened first holes.

33. A method of manufacturing a semiconductor device, the method comprising:
forming stack structures, wherein each of the stack structures includes first access lines and first insulating layers that are alternately stacked, and extends in a first direction;
forming insulating pillars extending through the stack structures, wherein at least one of the insulating pillars includes an air gap therein;
forming electrode pillars extending through the stack structures; and
forming second access lines connected to the insulating pillars and the electrode pillars and extending in a second direction that crosses the first direction.

34. The method of claim 33, wherein, in each of the stack structures, the method further comprises:
forming first openings by selectively etching the first insulating layers exposed through sidewalls of the stack structure; and
forming first sealing layers defining first air gaps positioned in the first openings, the first air gaps extending in the first direction.

35. The method of claim 33, wherein, in each of the stack structures, the method further comprising:
forming holes extending through the stack structure;
forming second openings by selectively etching the first insulating layers exposed through the holes; and
forming second sealing layers defining second air gaps positioned in the second openings.

36. The method of claim 35, wherein the electrode pillars are formed in the holes.

37. The method of claim 35, wherein the insulating pillars are formed in the holes.

38. The method of claim 37, wherein forming the electrode pillars comprises:
reopening some of the holes by removing some of the insulating pillars; and
forming the electrode pillars in the reopened holes.
